(19) United States
(12) Patent Application Publication
(10) Pub. No.: US 2010/0139755 A1
(43) Pub. Date: Jun. 10, 2010

(54) FRONT CONNECTED PHOTOVOLTAIC ASSEMBLY AND ASSOCIATED METHODS

(75) Inventors: Christopher J. Petti, Mountain View, CA (US); Mohamed M. Hilali, Sunnyvale, CA (US); S. Brad Herner, San Jose, CA (US)

Correspondence Address: THE MUELLER LAW OFFICE, P.C., 12951 Harwick Lane, San Diego, CA, 92130, US

(73) Assignee: Twin Creeks Technologies, Inc., San Jose, CA (US)

(21) Appl. No.: 12/331,376

(22) Filed: Dec. 9, 2008

(51) Int. Cl. H01L 31/00; H01L 31/18

(52) U.S. Cl. 136/256; 438/57; 257/E21.211

(57) ABSTRACT

A photovoltaic device is disclosed herein that, in various aspects, includes a conductive layer, and a substantially crystalline lamina with a first surface oriented toward the conductive layer and a second surface oriented away from the conductive layer. The lamina thickness is within the range between about 0.2 microns and about 50 microns. An aperture passes through the lamina from the first surface to the second surface. A connector in electrical communication with the conductive layer is disposed through the aperture. Methods of manufacture of the photovoltaic devise are also disclosed.

### BACKGROUND OF THE INVENTION

A photovoltaic cell generates electric current from light. The standard photovoltaic cell is a body formed from a semiconductor material such as silicon. The body may be, for example, a silicon wafer, or may be a layer of deposited amorphous or polycrystalline silicon. The body is doped with p-type and n-type dopants to form p-type and n-type regions and a p-n junction between the p-type and n-type regions. The dopant concentration of one region may be higher than that of the other, in which case the p-n junction is either a p−-n+ junction or a p+-n− junction. The more lightly doped region is known as the base of the photovoltaic cell, while the more heavily doped region is known as the emitter. Most carriers are generated within the base, and it is typically the thickest portion of the cell. The base and emitter together form the active region of the cell.

Photons absorbed by the semiconductor material increase the energy of the electrons of the material thereby creating charge carriers (electrons and holes) on either side of the p-n junction within the cell, which then migrate across the p-n junction thereby producing an electrical current. Ohmic metal-semiconductor contacts are made to both the n-type and p-type sides of the cell to collect the resulting electrical current from the cell.

When the cell is formed from a semiconductor wafer, the wafer may be affixed to a substrate or a superstrate. In general, the process wherein these conventional cells are affixed to receiver elements allows some non-planarity on either surface. Thus, for example, wires can be soldered directly onto the cell to connect to the ohmic-metal semiconductor contact and thence a side of the p-n junction. Because of the allowable non-planarity, the cell can then be affixed to the substrate or superstrate such that the wires intervene between the cell and the substrate or superstrate.

If, as will be described, wires and suchlike cannot intervene between the photovoltaic cell and the supporting substrate or superstrate because of the thinness of the photovoltaic cell, or if the process used to affix the photovoltaic cell to the supporting substrate precludes interposing such structures, new apparatus and associated methods are required to make electrical contact to the portion of the cell affixed to the substrate or superstrate.

### BRIEF SUMMARY OF THE INVENTION

Improvements and advantages may be recognized by those of ordinary skill in the art upon study of the present disclosure. In various aspects, the photovoltaic device disclosed herein includes a conductive layer, and a substantially crystalline lamina with a first surface oriented toward the conductive layer and a second surface oriented away from the conductive layer. The lamina thickness is within the range between about 0.2 micron and about 50 microns in various aspects. An aperture passes through the lamina from the first surface to the second surface, and a connector in electrical communication with the conductive layer is disposed through the aperture.

### BRIEF DESCRIPTION OF THE DRAWINGS

FIG. 1A illustrates by cross-sectional view an exemplary implementation of a photovoltaic device;

FIG. 1B illustrates by top view the exemplary implementation of the photovoltaic device of FIG. 1A;

FIG. 2A illustrates by cross-sectional view an exemplary implementation of a pair of photovoltaic devices connected to one another in series;

FIG. 2B illustrates by top view the exemplary implementation of the pair of photovoltaic devices connected to one another in series of FIG. 2A;

FIG. 3 illustrates by cross-sectional view another exemplary implementation of a photovoltaic device;

FIG. 4A illustrates by cross-sectional view an exemplary implementation of a connector;

FIG. 4B illustrates by cross-sectional view a second exemplary implementation of a connector;

FIG. 4C illustrates by cross-sectional view a third exemplary implementation of a connector; and

FIG. 4D illustrates by cross-sectional view a fourth exemplary implementation of a connector.

FIG. 5 illustrates by cross-sectional view a portion of a photovoltaic device including an exemplary implementation of a connection between a connector and a conductive layer.

FIG. 6 illustrates by process overview flowchart an exemplary method of manufacture of a photovoltaic device.

The Figures are exemplary only and the implementations illustrated therein are selected to facilitate explanation. The number, position, relationship and dimensions of the parts shown in the Figures to form the various implementations described herein, as well as dimensions and dimensional proportions to conform to specific force, weight, strength, flow and similar requirements, are explained herein or are understandable to a person of ordinary skill in the art upon study of this disclosure. Where used in various Figures, the same numerals designate the same or similar parts. Furthermore, when the terms “top,” “bottom,” “right,” “left,” “forward,” “rear,” “first,” “second,” “inside,” “outside,” and similar terms are used, the terms should be understood in reference to the orientation of the structures shown in the drawings and are utilized to facilitate understanding.

### DETAILED DESCRIPTION

The photovoltaic device of the current invention may be utilized in ways generally described in Sivaram et al., U.S. patent application Ser. No. 12/026530, entitled “Method to Form a Photovoltaic Cell Comprising a Thin Lamina,” filed Feb. 5, 2008, owned by the assignee of the present application (Sivaram et al.) and hereby incorporated by reference herein in its entirety for any and all purposes. Details of the possible construction of the photovoltaic assembly in various aspects are disclosed in Sivaram et al., and also in Herner, U.S. patent application Ser. No. 12/057,265, entitled “Method to Form a Photovoltaic Cell Comprising a Thin Lamina Bonded to a Discrete Receiver Element,” filed Mar. 27, 2008, owned by the assignee of the present application and hereby incorporated by reference herein in its entirety for any and all purposes.

The thin lamina of the present invention may be formed from a donor wafer. The donor wafer and, thus, the lamina may be composed of silicon, silicon based semiconductor material, or other semiconductor materials such as the III-V, III-IV classes of semiconductors. The donor wafer material may be monocrystalline, polycrystalline, or multicrystalline in structure, and may include intentionally or accidentally induced defects and/or dopants. A monocrystalline wafer is composed substantially of a single crystal, although the crystal may include internal and/or surface defects either inherent or purposely formed such as lattice defects. Certain dopants included therein may affect the structure of the crystal. The term multicrystalline typically refers to material having crystals that are on the order of a millimeter in size. Polycrystalline material has smaller grains, on the order of a thousand angstroms. Monocrystalline, multicrystalline, and polycrystalline material is typically entirely or almost entirely crystalline, with no or almost no amorphous matrix. For example, non-deposited semiconductor material is at least 80 percent crystalline. In various aspects, the lamina forms at least a portion of a base and/or at least a portion of an emitter of a photovoltaic cell.

An exemplary donor wafer may be a monocrystalline silicon wafer of any practical thickness, for example from about 300 to about 1000 microns thick and the donor wafer may be any shape including, for example, circular, square, or octagonal. The donor wafer may be any size, though standard wafer sizes may be preferred, as standard equipment exists for handling them. Standard wafer sizes are 100 mm, 125 mm, 150 mm, 200 mm, and 300 mm. In alternative implementations, the wafer may be thicker with the maximum thickness limited only by practicalities of wafer handling. Alternatively, polycrystalline or multicrystalline silicon may be used, as may microcrystalline silicon, or wafers or ingots of other semiconductor material.

In order to form the lamina from the donor wafer, a surface of the donor wafer may be treated, for example, by texturing and/or doping. In some aspects, the entire surface of the donor wafer is doped, while, in other aspects, only region(s) of the surface of the donor wafer are doped. In addition, one or more layers may be formed upon the surface of the donor wafer by, for example, deposition. After treatment, if any, of the surface of the donor wafer, and the formation of layer(s), if any, on the surface of the donor wafer, one or more species of gas ions such as hydrogen and/or helium are implanted into the donor wafer through the surface of the donor wafer and through any additional layer(s) deposited upon the surface of the donor wafer. The gas ions produce damage in the lattice of the donor wafer material that defines a cleave plane within the donor wafer. Following the formation of the cleave plane, the conductive layer is formed on the surface through which the gas ions were implanted, on the surface of a receiver element, or both.

The conductive layer may be composed of various metals, metal oxides, or other electrically conductive materials, and may be formed by, for example, deposition, sputtering, or other appropriate method. For example, the conductive layer may be formed from metal such as silver, gold, platinum, titanium, aluminum, chromium, molybdenum, tantalum, zirconium, vanadium, indium, cobalt, antimony, and tungsten, and alloys thereof. The conductive layer may be formed of metal oxides that may be transparent such as aluminum-doped zinc oxide, indium tin oxide, tin oxide, or titanium oxide. The conductive layer may be formed as a combination of metals and/or metal oxides. For example, in some implementations, the conductive layer may be deposited on the receiver element and a conductive layer of a different metal or metal oxide may be deposited above the surface of the donor wafer.

Heating of the donor wafer to an exfoliation temperature causes the portion of the donor wafer between the surface through which the gas ion were implanted and the cleave plane to exfoliate from the donor wafer. The donor wafer is secured to the receiver element with the conductive layer intervening between the donor wafer and the receiver element such that, when exfoliation occurs, the lamina that is formed upon exfoliation is secured in fixed relation to the receiver element with the conductive layer intervening between the lamina and the receiver element. Thus, the lamina is supported by the receiver element as the lamina is formed from the donor wafer. In various aspects, the donor wafer may be secured to the receiver element and then heated to the exfoliation temperature to exfoliate the lamina, or the donor wafer may be bonded to the receiver element at the exfoliation temperature but prior to the exfoliation of the lamina from the donor wafer. Following exfoliation, the lamina may be subjected to additional processing such as doping through the exfoliated surface, texturing of the exfoliated surface, deposition of additional layers upon the exfoliated surface, and so forth. The thickness of the lamina may range from between about 0.2 micron and about 100 microns in various aspects. Further details including, inter alia, methods for transferring the lamina from the donor wafer to the receiver element with the conductive layer interposed between the lamina and the receiver element are disclosed in Agarwal et al., U.S. patent application Ser. No. 12/335,479, entitled “Methods of Transferring a Lamina to a Receiver Element,” filed Dec. 15, 2008, owned by the assignee of the present application and hereby incorporated by reference herein in its entirety for any and all purposes.

The receiver element may be composed of, for example, glass including oxide glass, glass-ceramic, oxide glass-ceramic, of metal and/or metal oxide, or of polymer. In various aspects, the receiver element may be composed of metal such as steel or aluminum, metal oxide, polymer, or combinations thereof. The receiver element, in some aspects, may be composed of donor wafer material. A plurality of materials may be used to form the receiver element, and the resultant receiver element may have a layered structure. In some aspects involving photovoltaic applications, the receiver element may be either a substrate or a superstrate, and, when a superstrate, may be transparent, for example, in the infrared, visible, and/or ultraviolet wavelengths. In one exemplary aspect, the receiver element is float glass, and is between about 200 microns and about 800 microns thick. In some implementations, the receiving surface of the receiver element generally conforms to the first surface of the donor wafer.

Because the thickness of the lamina may range from between about 0.2 micron and about 100 microns, the lamina is fragile, and is supported by the receiver element as the lamina is formed from the donor wafer in order to avoid breakage or other damage. The lamina only exists as secured in fixed relation to the receiver element, so that the bonding-exfoliation process does not allow access to the first side of the lamina, which is secured to the receiver element, to form an electrical connection thereto. Wire(s) and suchlike may not intervene between the lamina and the receiver element as the wire(s) would interfere with exfoliation and/or the bond between the lamina and the receiver element. Accordingly, as disclosed herein, the conductive layer may form an electrical connection generally to a side of a p-n junction located within the photovoltaic device. An aperture passes through the lamina from the first lamina surface to the second lamina surface, and the connector is located within the aperture in electrical communication with the conductive layer

The Figures referenced herein generally illustrate various exemplary implementations of the photovoltaic device and methods. These illustrated implementations are not meant to limit the scope of coverage, but, instead, to assist in understanding the context of the language used in this specification and in the claims. Accordingly, variations of the photovoltaic device and methods that differ from these illustrated implementations may be encompassed by the appended claims that alone define the invention.

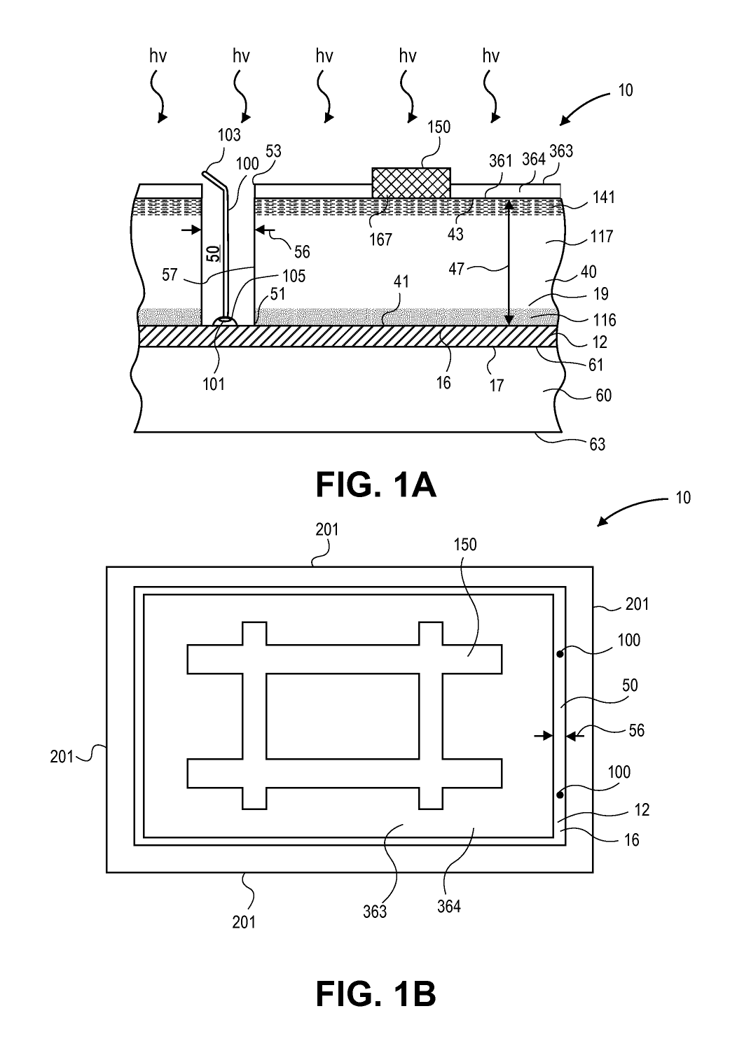

As illustrated in FIGS. 1A and 1B, the photovoltaic device 10 includes a lamina 40 with a first lamina surface 41 that is secured to conductive layer 12 that, in turn, is secured to receiver element 60, and an opposing second lamina surface 43 that is formed when the lamina 40 is exfoliated from the donor wafer (not shown). The photovoltaic device 10 is generally adapted to convert light into electrical energy and includes a photovoltaic cell with a p-n junction 19 therein and may further include, for example, various structures that control reflectivity and convey current from the photovoltaic device 10 in various implementations.

The donor wafer (not shown) and the lamina 40 formed from the donor wafer, in the implementation of FIGS. 1A and 1B, is lightly doped with a dopant of a first conductivity type which is illustrated as first region 117. A second region 116 extends into the lamina 40 from lamina surface 41, as illustrated. The second heavily doped region 116 is formed by diffusion doping through surface 41 of the lamina 40 with a dopant of a second conductivity type opposite to that of first region 117 prior to implantation of gas ions within the donor wafer and subsequent exfoliation of the lamina 40 from the donor wafer. The interface between the lightly doped region 117 and heavily doped layer 116 defines p-n junction 19. In other implementations, region 116 may be formed as a series of discrete heavily doped regions. The second region 116 is in electrical communication with the conductive layer 12 at lamina surface 41 of the lamina 40 and conductive layer surface 16 of the conductive layer 12, which are secured to one another as illustrated.

Dopant of the first conductivity type is diffused through the lamina surface 43 of the lamina 40 to form heavily doped region 141 that extends into the lamina 40 from the lamina surface 43 in this implementation. For example, if the first region 117 is n-type, an n-type dopant such as phosphorus may be diffused through lamina first surface 43 to form heavily doped region 141.

The photovoltaic device 10, in this implementation of FIGS. 1A and 1B, includes layer 364 deposited upon the second lamina surface 43 of the lamina 40. In various implementations, the layer 364 may be composed of a transparent dielectric material such as silicon nitride to form an anti-reflective coating (ARC). The layer 364 may be emplaced upon the lamina surface 243 of the lamina 240 by, for example, plasma-enhanced chemical vapor deposition. In various implementations, layer 364 is between about 500 Å and about 2000 Å thick, for example, about 650 Å thick.

Wire 150 is located above second lamina surface 43 such that the wire 150 is in electrical communication with heavily doped region 141 and, hence, region 117 in lamina 40. Wire 150 may be a finger, wire, trace, or other such electrical connector. Portions of the wire 150 in this implementation intrude through layer 364, as layer 364 may be dielectric, to be biased against second lamina surface 43 in order to be in electrical communication with the heavily doped region 141. Wire 150 may be formed following the deposition of the layer 364 upon the second lamina surface 43. For example, trenches 167 are formed in layer 364 by laser ablation, and may be between about 10 microns and about 50 microns wide. The pitch of trenches 167 is preferably between about 200 μm and about 1500 μm. The pitch and width of the trenches 167 can be adjusted to account for the material used to form wire 150 within a trench 167, the expected current, and so forth, as will be understood by those of ordinary skill in the art upon study of this disclosure. The wire 150 may be formed by plating or other techniques. For example, a nickel seed layer (not shown) may be emplaced within the trench 167 on second lamina surface 43 of lamina 40 followed by, for example, electroplating of copper, or conventional or light-induced plating of either silver or copper. These plating techniques selectively deposit the metal upon the second lamina surface 43 within trench 167 thereby forming the wire 150. The thickness of the wire 150 may be selected based upon the desired electrical resistance, and may range, for example, from about 7 microns to about 10 microns.

In other implementations (not shown), the heavily doped region 141 may be localized about the trench 167 to provide electrical communication between the wire 150 and the region 117 in lamina 40. For example, following the formation of the trench 167, a source of dopant is emplaced on the regions of second lamina surface 43 of lamina 40 exposed by trenches 167 by, for example, screen printing, aerosol printing, or inkjet printing. Passing a laser beam over the regions of second lamina surface 43 with the dopant source emplaced thereon results in heavily doped regions proximate the second lamina surface 43 about the trench 167. Laser heating of lamina 40 may be very local, typically only tens of nanometers deep and thus avoids exposing the lamina 40 generally to high temperatures that may result in damage to the lamina 40, damage to the receiver element 60, damage to the bond between the lamina 40 and the receiver element 60, and/or contamination of the lamina 40 by the bonding material. This and other apparatus and methods that avoid exposure of the lamina to high temperatures are disclosed in Hilali et al., U.S. patent application Ser. No. 12/189158, “Photovoltaic Cell Comprising a Thin Lamina Having a Rear Junction and Method of Making,” filed Aug. 10, 2008, owned by the assignee of the present application, and hereby incorporated by reference herein in its entirety for any and all purposes. In other implementations, the layer 364 may be composed of a transparent conductive oxide such as aluminum-doped zinc oxide, indium tin oxide, tin oxide, or titanium oxide and in electrical communication with the heavily doped region 141 so that the wire 150 may be in contact therewith or omitted entirely.

As illustrated in FIGS. 1A and 1B, an aperture 50 passes through the lamina 40 between the first lamina surface 41 and the second lamina surface 43. The aperture 50, as illustrated, passes through layer 364 between layer surface 361 and the layer surface 363, to be generally aligned with the portion of the aperture 50 that passes between first lamina surface 41 and second lamina surface 43. The aperture 50 opens upon the conductive layer 12 at aperture end 51 and upon layer surface 363 at aperture end 53.

The aperture 50 may be formed, for example, by laser cutting or chemical etching. A solid-state Nd:YAG laser may be used to form the aperture 50. The laser wavelength may be 1064 μm, which has the most power and, therefore, throughput. Other wavelengths such as 532 nm or 355 nm, which may make narrower apertures with less damage to the surrounding lamina 40 and other structures, may be utilized. The laser is pulsed in the 10 nsec to 100 nsec range in various implementations.

A connector 100, as illustrated, is positioned within the aperture 50 between aperture end 51 and aperture end 53. As illustrated, the connector 100 is positioned within the portion of the aperture 50 that passes through the lamina 40 between first lamina surface 41 and second lamina surface 43 and the portion of the aperture 50 that passes through layer 364 between layer surface 361 and layer surface 363.

The connector 100 may be generally formed from various conductive materials such as, for example, copper, silver, aluminum, platinum, gold, or alloys thereof. As illustrated, the connector 100 is disposed within the aperture 50 to avoid contact with the aperture wall 57 that might result in the formation of shunts within the lamina 40, and, accordingly, the connector 100 may be sized to fit within the aperture width 56 of aperture 50 and/or the aperture width 56 of the aperture 50 may be chosen to accommodate the connector 100. In some implementations, the conductive material of the connector 100 may be coated with a dielectric so that the connector 100 could contact the aperture wall 57 without forming a shunt. The connector 100 may have any of a variety of cross-sectional shapes. For example, the connector 100 may have a generally round cross-section, or may be formed as a strip with a rectangular cross section.

The connector end 101 of the connector 100 is secured to conductive layer 12 by joint 105 located about conductive layer surface 16 such that the connector 100 is in electrical communication with the conductive layer 12. The joint 105 may be formed by soldering, welding, or other such techniques recognized by those of ordinary skill in the art. In other implementations, the connector end 101 could be more directly secured to conductive layer 12 in other ways or secured to other layers or other elements to electrically communicate therethrough with the conductive layer 12. The connector end 103 of the connector 100 is illustrated as extending forth from the opening defined by the aperture end 53 of the aperture 50 within the layer surface 363 to allow electrical communication from connector end 103 through the connector 100 with the conductive layer 12 and, thence, the side of the p-n junction 19 that is in electrical communication with the conductive layer 12. In various implementations, structure(s) (not shown) may be located, for example, upon layer surface 363 to form a contact that communicates with the conducive layer 12 through connector 100, and various wires and so forth may be secured to the contact in order to electrically connect with the conductive layer 12. The structure(s) may be electrically isolated from the layer 364. In various other implementations, the connector end 103 may be located within the aperture 50 generally proximate the aperture end 53 or otherwise located with respect to the aperture end 53 of the aperture 50 such that the connector 100 forms a conductive pathway generally from the conductive layer 12 through the lamina 40. Note that the connector 100 is not electrically connecting the lamina surface 43 or other portions of region 141 and/or region 117 to conductive layer 12—i.e. the connector 100 is not short-circuiting the p-n junction 19. Rather, the connector 100 provides a connection to the conductive layer 12 through the lamina 40 to eliminate the need for wire(s) intervening between the lamina 40 and the receiver element 60 that may interfere with exfoliation and/or the bond between the lamina 40 and the receiver element 60, particularly in implementations wherein the thickness 47 of the lamina 40 ranges between about 0.2 micron and about 100 microns.

FIG. 1B illustrates a top view of the photovoltaic device 10. As illustrated, wire 150 is located upon layer surface 363 of layer 364. The aperture 50 passes about the periphery of the photovoltaic device 10 between layer surface 363 and conductive layer surface 16 of the conductive layer 12 in this implementation to isolate edge 201. The photovoltaic device 10 is rectangular but could have other shapes such as circular or hexagonal in other implementations, and the aperture 50 may pass peripherally thereabout. The width 56 of the aperture 50 may range from about 40 μm to about 100 μm. As illustrated, the width 56 of the aperture 50 is generally constant as the aperture 50 traverses the periphery of layer surface 363 including the portions where connectors 100 are located. In other implementations, the width 56 of the aperture 50 may be altered proximate the locations of the connectors 100 to accommodate the connectors 100. For example, the width 56 may be increased proximate the connectors 100 to accommodate the connectors 100 in comparison with the width 56 of the remaining portions of the aperture 50. The depth of the aperture 50 may vary as the aperture 50 traverses around the periphery. For example, the aperture 50 passes between the layer surface 363 and conductive layer surface 16 of the conductive layer 12 proximate the connectors 100 so that the connectors 100 may pass through the aperture 50 between the conductive layer surface 16 and the layer surface 363, while the remaining portions of the aperture 50 pass from the layer surface 363 generally through region 117 (see FIG. 1A) of the lamina 40, which may be sufficient for edge isolation. The aperture 50, as illustrated is an elongate trench that traverses the periphery of photovoltaic device 10. In other implementations, the aperture 50 is not restricted to the periphery but could be located about sundry portions of the layer surface 363, and, accordingly, the aperture 50 could have other geometric shapes such as a circular shape. Although two connectors 100 are illustrated in the implementation of FIG. 1B, a single connector 100 or any other number of connectors 100 may be included in various implementations.

In operation, photons hᵥ from a light source pass into the photovoltaic device 10 illustrated in FIGS. 1A and 1B through surface 363 into the lamina 40. Some photons may pass through the lamina 40 to be reflected from the conductive layer surface 16 of conductive layer 12 back into the lamina 40 in embodiments wherein the conductive layer surface 16 is reflective. The photons increase the energy of electrons within the lamina 40 from the valence band to the conduction band thereby generating charge carriers in the form of electrons and holes. The p-n junction 19 creates an electrical field that causes the charge carriers to migrate across the p-n junction 19 thereby producing a current. Wires 150 are located upon second lamina surface 43 to form an electrical connection to one side of the p-n junction 19, and connector 100 is connected to conductive layer 12 to form an electrical connection to the opposing side of the p-n junction 19. The resulting current may then be transmitted from the photovoltaic assembly 10 from the one or more wires 150 or from the connector end 103 of the connector 100, as illustrated.

In other implementations (not illustrated), the receiver element 60 is a superstrate and is generally oriented toward the light source such that the photons pass into the photovoltaic device through receiver element surface 63 (see FIG. 1A). In such an implementation, the receiver element is transparent and the conductive layer 12 is formed of a generally transparent material such as a metal oxide, and a reflective layer may be deposited upon lamina surface 43.

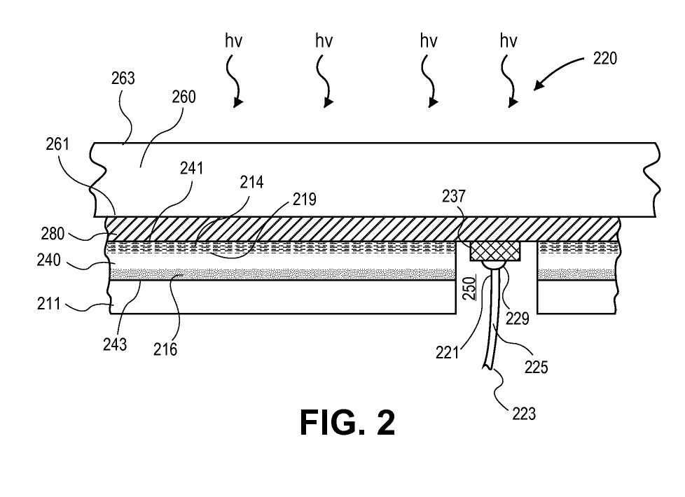

FIGS. 2A and 2B illustrate an implementation wherein photovoltaic device 400 is connected in series with photovoltaic device 600 by connector 500 that extends from conductive layer 412 in photovoltaic device 400 to wire 750 in photovoltaic device 600. As illustrated, photovoltaic device 400 includes lamina 440 with first lamina surface 441 secured to conductive layer surface 416 of conductive layer 412. The conductive layer surface 417 of conductive layer 412 is secured to receiver element surface 461 of the receiver element 460, and receiver element surface 463 of receiver element 460 is secured to panel 774. The panel 774 is a substrate in this implementation and may be made of metal, polymer, glass or other such materials. In other implementations (not shown), the panel 774 may be a superstrate and, accordingly, may be made of glass or other transparent material.

The photovoltaic device, in the implementation illustrated in FIGS. 2A and 2B, includes layer 564, which is deposited upon second lamina surface 443 to form an ARC thereupon. Layer surface 561 of layer 564 is in contact with second lamina surface 443 of lamina 440. The lamina 440 includes heavily doped region 541 and first region 517 of a first conductivity type. The lamina 440 includes heavily doped second region 516 of a second conductivity type opposite the first conductivity type. The first region 517 and second region 516 define p-n junction 419 generally proximate the first lamina surface 441 of lamina 440, as illustrated. When exposed to sunlight, photons hᵥ pass through layer surface 564 into the lamina 440, and charge carriers produced within the lamina 440 by the photons hᵥ migrate across the p-n junction 419 to produce a current.

Wire 550 is located about second lamina surface 443 and is in electrical communication with heavily doped region 541 and, thence, first region 517 in lamina 440, as illustrated in FIG. 2A. The conductive layer 412 is in electrical communication with the second region 516 at first lamina surface 441 of the lamina 440. Accordingly, in this implementation, wire 550 and conductive layer 412 are in electrical communication with the opposing sides of the p-n junction 419, so that current produced about the p-n junction 419 may be separated to the wire 550 and to the conductive layer 412, respectively.

As illustrated in FIG. 2A, photovoltaic device 600 includes lamina 640 with first lamina surface 641 secured to conductive layer surface 616 of conductive layer 612. The conductive layer surface 617 of conductive layer 612 is secured to receiver element surface 661 of the receiver element 660, and receiver element surface 663 of receiver element 660 is secured to panel 774. The photovoltaic device 600, as illustrated, includes layer 764, which is deposited upon second lamina surface 643 to form an ARC thereupon. The lamina 640 includes heavily doped region 741 and lightly doped first region 717 of a first conductivity type, and heavily doped second region 716 of a second conductivity type opposite the first conductivity type. As illustrated, the conductivity type of first region 717 and region 741 in photovoltaic device 600 correspond to the conductivity type of the first region 517 and region 541 in photovoltaic device 400, and the conductivity type of the second region 716 in photovoltaic device 600 corresponds to the conductivity type of second region 516 in photovoltaic device 400. The first region 717 and second region 716 define p-n junction 619 generally proximate the first lamina surface 641, as illustrated. Charge carriers produced within the lamina 640 by the photons hᵥ migrate across the p-n junction 619 to produce a current. Wire 750 is located about second lamina surface 643 and is in electrical communication with heavily doped region 741 and, thence, first region 717 in lamina 640, as illustrated in FIG. 2A. The conductive layer 612 is in electrical communication with the heavily doped second region 716 at first lamina surface 641 of the lamina 640. Accordingly, in this implementation, wire 750 and conductive layer 612 are in electrical communication with the opposing sides of the p-n junction 619, so that current produced about the p-n junction 619 may be separated to the wire 750 and to the conductive layer 612, respectively.

Aperture 450 passes through portions of the photovoltaic device 400 from the conductive layer surface 416 through the lamina 440 from first lamina surface 441 to second lamina surface 443 and through layer 564 from layer surface 561 to layer surface 563, as illustrated in FIG. 2A. Connector 500 is positioned within the aperture 450 with connector end 501 secured to conductive layer surface 416 of conductive layer 412 such that the connector is in electrical communication with the conductive layer 412. Connector end 503 is secured to wire 750 of photovoltaic device 600 such that the conductive layer 412 is in electrical communication with wire 750, and, thus, photovoltaic assembly 400 is connected in series with photovoltaic assembly 600. Aperture 650 passes through portions of the photovoltaic device 600 from the conductive layer surface 616 through the lamina 640 from first lamina surface 641 to second lamina surface 643 and through layer 764 from layer surface 761 to layer surface 763, as illustrated in FIG. 2A.

FIG. 2B illustrates a top view of the photovoltaic device 400 connected in series with photovoltaic device 600. As illustrated, apertures 450, 650 pass about the peripheries of photovoltaic devices 400, 600 respectively to isolate the edges thereof, and connectors may pass through apertures 450, 650 to communicate with the conductive layers 412, 612. As illustrated, connector end 501 of connector 500 is secured to conductive layer surface 416 of conductive layer 412. The connector 500 passes through the aperture 450 from photovoltaic device 400 to photovoltaic device 600 and is secured to wire 750 by connector end 503 to connect photovoltaic device 400 to photovoltaic device 600 in series. As illustrated in FIG. 2A, receiver element surfaces 463, 663 of photovoltaic assemblies 400, 600 respectively are attached to panel 774. Additional photovoltaic devices (not shown) may be located about the panel 774 and additional connectors (not shown) may be provided to connect photovoltaic devices 400, 600 with other photovoltaic devices in various implementations.

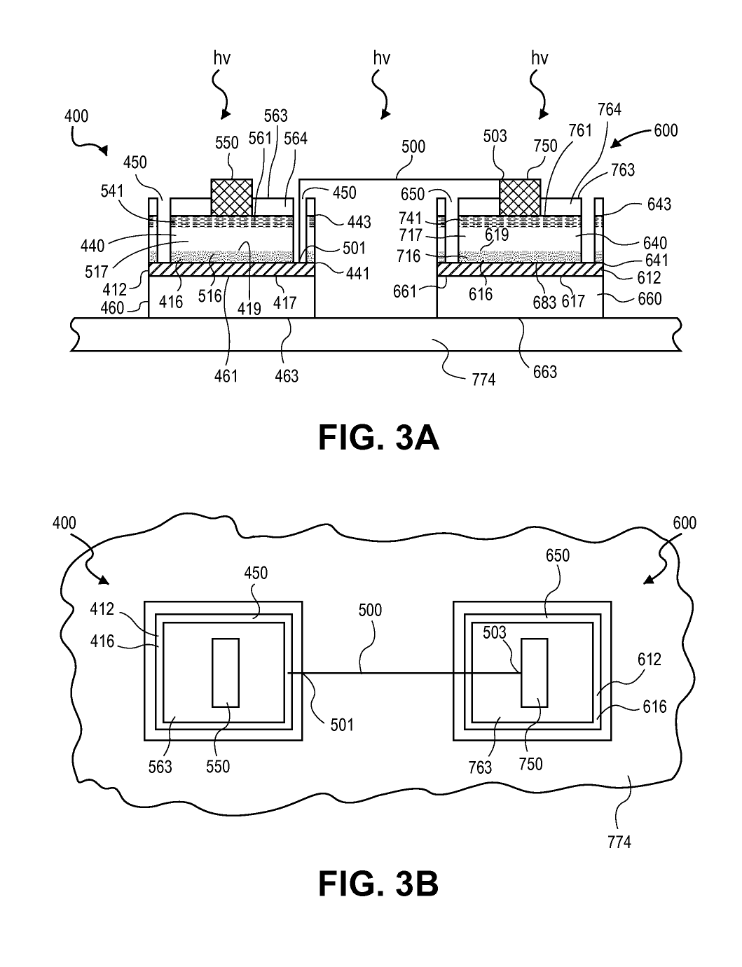

As illustrated in FIG. 3, aperture 850 passes through lamina 840 and a plurality of layers deposited upon lamina 840. In this implementation, the donor wafer and, hence, the lamina 840 cleaved from the donor wafer are lightly doped to a first conductivity type. As in the previously described implementation, the donor wafer surface is doped to a second conductivity type, opposite to that of the lamina 840, prior to cleaving. Reflective conductive layer 812 is formed on the doped surface of the donor wafer, on receiver element 860, or both. The resulting lamina 840 is secured in fixed relation to receiver element 860 with conductive layer 812 interposed between the lamina 840 and the receiver element 860 in photovoltaic device 800 illustrated in FIG. 3.

As illustrated in FIG. 3, photovoltaic device 800 includes intrinsic amorphous silicon layer 876 deposited on second lamina surface 843, which is formed upon exfoliation of the lamina 840 from the donor wafer, followed by an amorphous silicon layer 878 doped to a the first conductivity type upon layer 876. The combined thickness of amorphous layers 876 and 878 may be between about 200 Å and about 500 Å, for example about 350 Å. In one implementation, intrinsic layer 876 is about 50 Å thick, while doped layer 878 is about 300 Å thick. Layer 864, which is formed upon layer 878 acts both as an ARC and to lower the sheet resistance of the top cell contact in this implementation. Layer 864 may be composed of a transparent conductive oxide (TCO) such as, for example, indium tin oxide, tin oxide, titanium oxide, zinc oxide, and suchlike. The TCO may be between about 500 Å and 1500 Å thick, for example, about 900 Å thick. Wire 857, which is in electrical communication with layer 878, is located on antireflective layer 864. Wire 857 can be formed by any appropriate method.

In this implementation illustrated in FIG. 3, lamina 840 is the base, or a portion of the base, of the photovoltaic cell. Heavily doped amorphous layer 878 forms the contact to the base. Amorphous layer 876 is intrinsic, but layer 876 is thin enough to allow carriers to tunnel across. It functions as a buffer layer between the crystalline base and the amorphous silicon contact layer 878, allowing less recombination of generated carriers at this interface. Conductive layer 812 is in electrical communication with the emitter region formed in the lamina 840.

As illustrated in FIG. 3, aperture 850 passes through layer 864, layer 878, layer 876, and through lamina 840 between first lamina surface 841 and second lamina surface 843 to conductive layer 812, as illustrated in FIG. 3. Connector 900, as illustrated, is secured by connector end 901 to be in electrical communication with conductive layer 812. The connector 900 passes through the aperture 850 and is illustrated with connector end 903 extending forth from the aperture 850 to afford an electrical connection therefrom to the conductive layer 812. Accordingly, electrical connection may be made to the base and to the emitter of the photovoltaic device 800 through connector end 903 of connector 900 and through wire 857, respectively.

A plurality of such photovoltaic devices 800 may be fabricated, and each inspected for defects and tested for performance and sorted. Photovoltaic devices may be affixed to panel 890 and electrically connected through one or more connectors 900.

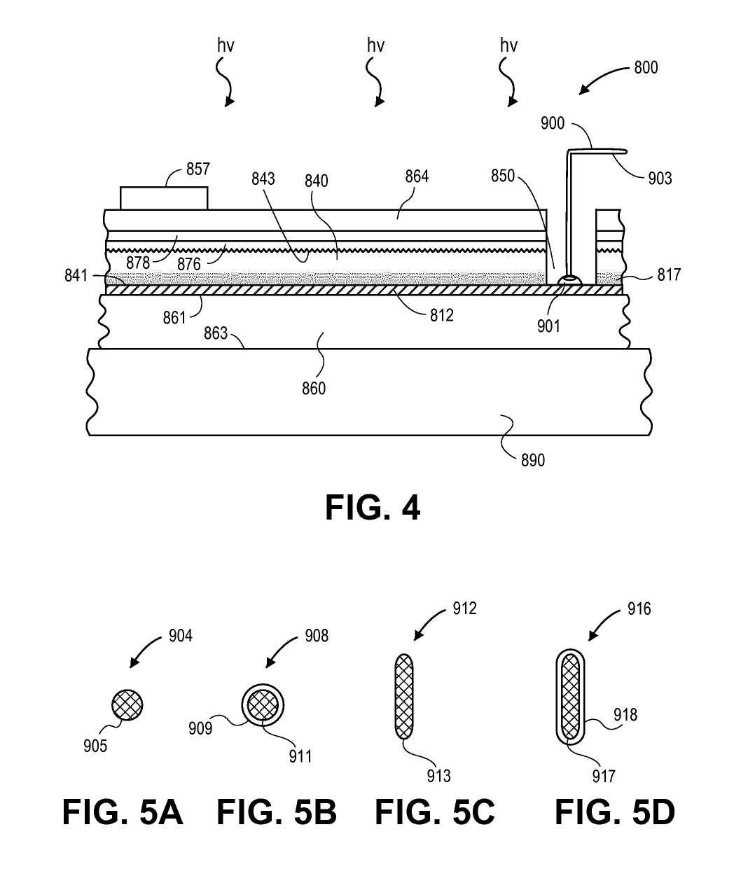

FIG. 4A illustrates a cross-section of a connector 904. In this implementation, the connector 904 includes a conductor 905 made of metal, other conductive materials, or combinations thereof. In FIG. 4B, a connector 908, as illustrated in cross-section, includes a conductor 911 surrounded by a layer 909 of insulating material such as a dielectric material. A connector 912 illustrated in FIG. 4C includes a strip of a conductor 913. FIG. 4D illustrates a connector 916, which includes a strip of a conductor 917 surrounded by a layer 918 of insulating material such as a dielectric material.

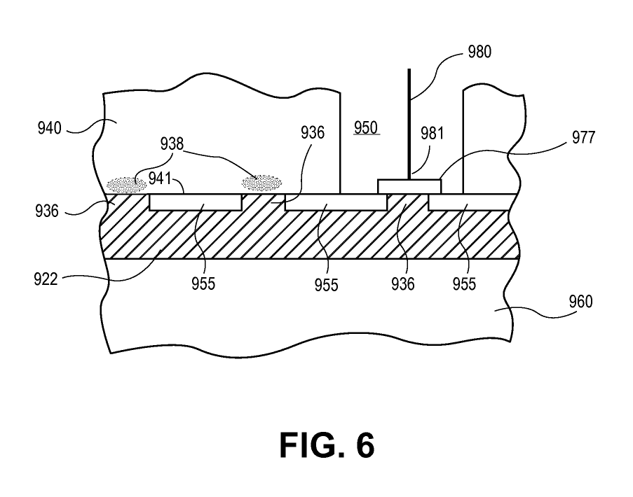

As illustrated in FIG. 5, a connector 980 may be electrically connected to a conductive layer 922 through a wire 977 including other intervening structures. In other implementations, other structures including various layers may intervene between the connector such as connector 980 and the conductive layer such as conductive layer 922, and the connector may electrically communicate with the conductive layer through these intervening structures. As illustrated in FIG. 5, lamina 940 is secured in fixed relation to receiver element 960 with layer 955 and layer 922 intervening between the first lamina surface 941 and the receiver element 960. In this implementation, layer 955 is formed from a dielectric, which may act as a diffusion barrier. The layer 955 may be composed of, for example, silicon nitride or SiO₂, and may be between about 1000 Å and about 1200 Å in thickness. Vias 936 are formed in layer 955, and first lamina surface 941 is exposed in each via 936. Note that in some implementations, the vias 936 are not trenches. A heavily doped region 938 may be formed within the lamina 940 proximate the vias 936, and the conductive layer 922 protrudes through the vias 936 to electrically communication with the heavily doped regions 938 in the lamina 940.

Aperture 950 extends through lamina 940 to the lamina first surface 941, as illustrated in FIG. 5. A wire 977 is formed in the aperture 950 upon the layer 955 and the portions of conductive layer 922 that extend through the vias 936 exposed by the aperture 950, and hence, the wire 977 is in electrical communication with the conductive layer 922. The wire 977 may be formed by screen-printing, photolithography, or other suitable method. Connector end 981 of connector 980 is secured to the wire 977 so that the connector 980 is in electrical communication with the conductive layer 922 in this implementation. In other implementations, portions of layer 955 exposed by the aperture 950 may be removed by chemical etching or other suitable method, and the connector end 981 of the connector 980 more directly secured to the conductive layer 922.

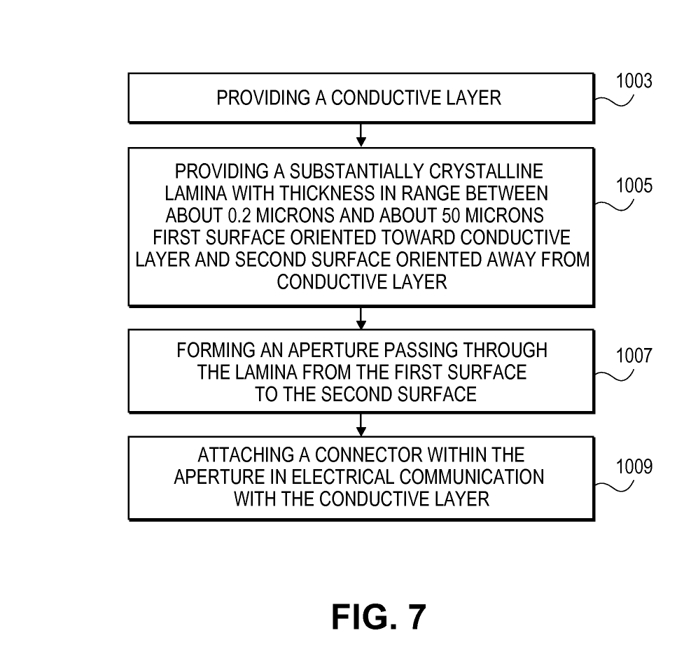

A method of manufacture of a photovoltaic assembly such as photovoltaic devices 10, 400, 600, 800, is outlined in the process overview flowchart of FIG. 6. As illustrated in FIG. 6, the process may include step 1003 of providing a conductive layer and step 1005 of providing a substantially crystalline lamina, such as lamina 40, 440, 640, 840, 940, with a first lamina surface, such as first lamina surface 41, 441, 641, 841, 941, oriented toward the conductive layer, such as conductive layer 12, 412, 612, 812, 922, and a second surface, such as second lamina surface 43, 443, 643, 843 oriented away from the conductive layer. The lamina thickness 47 being within the range between about 0.2 micron and about 50 microns. The process, as illustrated in FIG. 6, includes step 1007 of forming an aperture, such as aperture 50, 450, 650, 850, 950 passing through the lamina from the first surface to the second surface, and step 1009 of attaching a connector, such as connector 100, 500, 900, 904, 0908, 912, 916, 980, within the aperture in electrical communication with the conductive layer. In various implementations, the methods of manufacture may include a step of electrically linking the connector from the conductive layer to a wire, such as wire 150, 550, 750, 857 on a second photovoltaic device. In various aspects, the methods of manufacture may include a step of forming a wire above the second surface of the lamina. Step 1005 may include steps of implanting gas ions through a donor wafer surface of a donor wafer to form a cleave plane within the donor wafer, the donor wafer being doped to a first conductivity type, bonding the donor wafer surface with cleave plane formed therein to a receiver element with the conductive layer interposed between the donor wafer surface and the receiver element, and exfoliating the donor wafer along the cleave plane thereby forming the lamina. The methods of manufacture may include a step of doping the donor wafer through the donor wafer surface prior to implanting step. The methods of manufacture may include a step of texturing the donor wafer surface before the bonding step. The methods of manufacture may include a step of step of depositing one or more layers upon the donor wafer surface prior to the bonding step.

The foregoing along with the accompanying figures discloses and describes various exemplary implementations. Upon study thereof, one of ordinary skill in the art may readily recognize that various changes, modifications and variations can be made therein without departing from the spirit and scope of the inventions as defined in the following claims.

What is claimed is:

1. A photovoltaic device, comprising:
a conductive layer;
a substantially crystalline lamina with a first surface oriented toward the conductive layer and a second surface oriented away from the conductive layer, and the lamina thickness being within the range between about 0.2 micron and about 50 microns;
an aperture that passes through the lamina from the first surface to the second surface; and
a connector in electrical communication with the conductive layer and disposed through the aperture.

2. The device, as in claim 1, wherein the connector is electrically isolated from the lamina.

3. The device, as in claim 1, wherein the connector is also in electrical communication with a wire on second photovoltaic device.

4. The device, as in claim 1, further comprising:
one or more layers disposed between the first surface of the lamina and the conductive layer, and the aperture passing through the one or more layers.

5. The device, as in claim 1, further comprising:
one or more layers disposed upon the second surface of the lamina, the aperture passing through the one or more layers.

6. The device, as in claim 1, further comprising:
a receiver element secured to the conductive layer such that the conductive layer is located between the receiver element and the first surface of the lamina.

7. The device, as in claim 1, further comprising:
a wire disposed above the second surface of the lamina.

8. The device, as in claim 7, wherein the wire is coupled to the lamina at the second surface.

9. The device, as in claim 7, wherein the wire is in electrical communication with a second conductive layer on a second photovoltaic device.

10. The device, as in claim 1, wherein the aperture extends generally circumferentially about the lamina for edge isolation.

11. The device, as in claim 1, wherein the width of the aperture is within the range from about 50 μm to about 100 μm.

12. A method of manufacture of a photovoltaic assembly, comprising the steps of:
providing a conductive layer;
providing a substantially crystalline lamina with a first surface oriented toward the conductive layer and a second surface oriented away from the conductive layer, and the lamina thickness being within the range between about 0.2 micron and about 50 microns;
forming an aperture passing through the lamina from the first surface to the second surface; and
attaching a connector within the aperture in electrical communication with the conductive layer.

13. The method, as in claim 12, further comprising the step of electrically linking the connector from the conductive layer to a wire on a second photovoltaic device.

14. The method, as in claim 12, wherein the aperture extends generally circumferentially about the lamina for edge isolation.

15. The method, as in claim 12, further comprising the step of forming a wire above the second surface of the lamina.

16. The method, as in claim 12, wherein the step of providing a lamina further comprises the steps of:
implanting gas ions through a donor wafer surface of a donor wafer to form a cleave plane within the donor wafer, the donor wafer being doped to a first conductivity type;
bonding the donor wafer surface with cleave plane formed therein to a receiver element with the conductive layer interposed between the donor wafer surface and the receiver element; and
exfoliating the donor wafer along the cleave plane thereby forming the lamina.

17. The method, as in claim 17, further comprising the step of doping the donor wafer through the donor wafer surface prior to implanting step.

18. The method, as in claim 17, further comprising the step of texturing the donor wafer surface before the bonding step.

19. The method, as in claim 17, further comprises the step of depositing one or more layers upon the donor wafer surface prior to the bonding step.
